(19) United States
(12) Patent Application Publication
(10) Pub. No.: US 2006/0067393 A1
(43) Pub. Date: Mar. 30, 2006

(54) Equalizer For A Serial Data Communication Receiver

(76) Inventor: Hung-Cheng Fan, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 10/908,464

(22) Filed: May 12, 2005

(30) Foreign Application Priority Data
Sep. 30, 2004 (TW) 093129653

(51) Int. Cl. H03H 7/30

(52) U.S. Cl. 375/229; 333/18

(57) ABSTRACT

An equalizer for a serial data communication receiver includes: a first transistor including a first input terminal, a first output terminal, and a first equalization terminal; a second transistor including a second input terminal, a second output terminal, and a second equalization terminal; a first resistor coupled to the first output terminal of the first transistor; a second resistor coupled to the second output terminal of the second transistor; a third resistor coupled to the first equalization terminal of the first transistor; a fourth resistor coupled between the second equalization terminal of the second transistor and the third resistor; a current source coupled between the third resistor and the fourth resistor; a first capacitor coupled to the first equalization terminal of the first transistor; and a second capacitor coupled to the second equalization terminal of the second transistor.

### BACKGROUND OF INVENTION

1. Field of the Invention

The present invention provides an equalizer for a serial data communication receiver, and more particularly, an equalizer capable of using a MOS capacitor.

2. Description of the Prior Art

Regarding data communication in a computer system, parallel transmission methods can no longer fully satisfy increasing user demands for rapid transfer of comparatively large data files. For example, with the recent boom in the use of multimedia applications leading to higher and higher storage capacity requirements, computer systems have, out of necessity, entered a gigabyte age. This in turn has highlighted shortcomings in the bandwidths of conventional buses and interfaces, and thus, the birth of high-speed serial I/O systems, such as serial advanced technology attachment, or SATA, has resulted. Such systems are now commonly substituted for IDE, and systems such as peripheral component interconnect express, or PCI Express, are substituted for PCI/PCI-X. Previously developed parallel systems using relatively large 3-volt or 5-volt signal levels, are generally too un-wieldy for high-speed communication applications, while newer serial systems using small signals and having shorter rise and fall times, are significantly less prone to the problems affecting parallel systems. However, small-signal transmissions are, however, prone to interference by noise. As a result, small-signal transmissions not only use 8b/10b coding for increasing the identification rate of transmitted bits, but also differential signals of ±0.25 volts for substituting for single ended signals, so as to increase noise tolerance.

In addition, small-signal transmissions need to resist ‘channel response effect’, which is an effect whereby a gain of a channel decreases significantly and suddenly at a frequency or frequency range owing to the channel's material. Channel response effect prevents signals in the channel from being transmitted at the frequency or frequency range, so an equalizer is added to the serial system for compensating for the channel response effect.

Please refer to FIG. 1, which illustrates a circuit diagram of a prior art equalizer 10 of a serial data communication receiver. The equalizer 10 includes transistors 12 and 14, resistors 16, 18, and 20, a capacitor 22, and current sources 24 and 26. The transistors 12 and 14 are metal oxide semiconductor field effect transistors (MOSFET). The resistors 16 and 18 connect to drains D of the transistors 12 and 14 respectively as active loads of the transistors 12 and 14. The resistors 16 and 18 also connect to a constant-voltage source (not shown in FIG. 1) for biasing the transistors 12 and 14 to proper operating voltage. Gates of the transistors 12 and 14 receive signals V_{IN1} and V_{IN2} respectively, so as to form a differential signal V_{D}(V_{D}=V_{IN1}−V_{IN2}). The transistors 12 and 14 amplify the differential signal V_{D}, and output a corresponding signal Vo from the drains D of the transistors 12 and 14. Sources S of the transistors 12 and 14, coupled to each other through a parallel connection of the resistor 20 and the capacitor 22, form a common mode structure. The current sources 24 and 26 sink current provided by the transistors 12 and 14 from the sources S for maintaining stability. Operations of the equalizer 10 are well known in the art, so this paragraph will not disclose further. Moreover, because the capacitor 22 can be seen as a line with zero resistance at high frequency, the equalizer 10 generates an extremely high gain (infinity being the ideal) at high frequency, which compensates for the effects of channel response effect. That is, with the addition of the equalizer 10, the serial data communication receiver gains increased bandwidth, so as to resist noise. However, the amplitude of the differential input signal of the equalizer 10 should be small enough to meet the high-speed operation requirements, so a cross voltage of the capacitor 22 providing a main pole of the equalizer 10 at high frequency should be suitably small. Moreover, when a cross voltage of a MOS (or, metal oxide semiconductor) capacitor is small, the capacitance of the MOS capacitor becomes proportionally small. As a result, an MOS capacitor is unsuitable for use in the capacitor 22 application, rather an MMC (multi-metal capacitor) or a PolyC (poly capacitor) type capacitor (these having properties for preventing the capacitance of capacitor 22 from decreasing when the input signals of the transistors 12 and 14 are close to each other), are generally used. Nevertheless, the MMC capacitor or the poly-capacitor leads to higher production costs and complexity than the MOS capacitor, and the prior art equalizer needed to compensate the effects of channel response effect incurs a significant increase system resource overheads.

### SUMMARY OF INVENTION

It is therefore a primary objective of the claimed invention to provide an equalizer for a serial data communication receiver.

According to the claimed invention, an equalizer for a serial data communication receiver includes a first transistor comprising a first input terminal, a first output terminal and a first equalization terminal, a second transistor comprising a second input terminal, a second output terminal and a second equalization terminal, a first resistor coupled to the first output terminal of the first transistor, a second resistor coupled to the second output terminal of the second transistor, a third resistor coupled to the first equalization terminal of the first transistor, a fourth resistor coupled between the second equalization terminal of the second transistor and the third resistor, a current source coupled between the third resistor and the fourth resistor, a first capacitor coupled to the first equalization terminal of the first transistor, and a second capacitor coupled to the second equalization terminal of the second transistor.

The claimed invention further discloses an equalizer for a serial data communication receiver. The equalizer includes a first transistor comprising a first input terminal, a first output terminal and a first equalization terminal, a second transistor comprising a second input terminal, a second output terminal and a second equalization terminal, a resistor coupled to the first output terminal of the first transistor, a second resistor coupled to the second output terminal of the second transistor, a third resistor coupled between the first equalization terminal of the first transistor and the second equalization terminal of the second transistor, a first current source coupled to the first equalization terminal of the first transistor, a second current source coupled to the second equalization terminal of the second transistor, a first capacitor coupled to the first equalization terminal of the first transistor, and a second capacitor coupled to the second equalization terminal of the second transistor.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates a circuit diagram of a prior art equalizer of a serial data communication receiver.

FIG. 2 illustrates a circuit diagram of a preferred embodiment equalizer of a serial data communication receiver in accordance with the present invention.

FIG. 3 illustrates a frequency-response diagram of the equalizer in FIG. 2.

FIG. 4 illustrates a waveform diagram of input/output signals of the equalizer in FIG. 2.

FIG. 5 illustrates a circuit diagram of another embodiment equalizer in accordance with the present invention.

### DETAILED DESCRIPTION

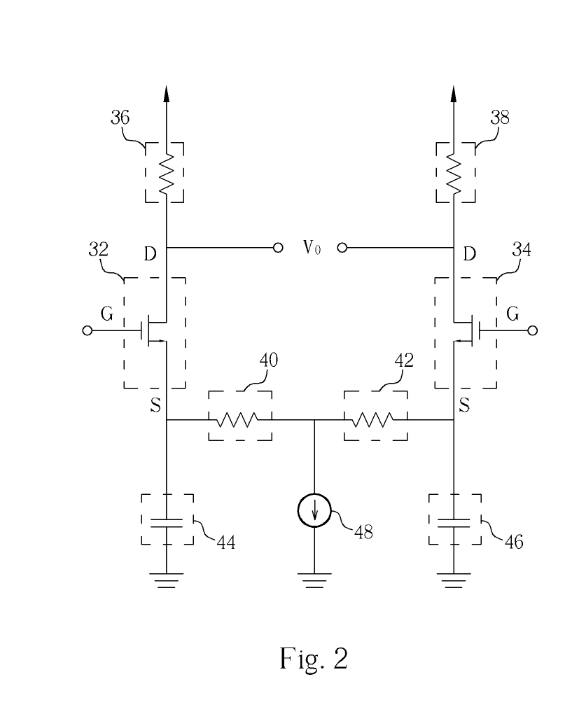

Please refer to FIG. 2, which illustrates a schematic diagram of a preferred embodiment equalizer 30 of a serial data communication receiver in accordance with the present invention. The equalizer 30 includes transistors 32, 34, resistors 36, 38, 40, 42, capacitors 44, 46, and a current source 48. The transistors 32 and 34 are MOSFETs. The resistors 36 and 38 connect to drains D of the transistors 32 and 34 respectively as active loads of the transistors 32 and 34. The resistors 36 and 38 also connect to a constant-voltage source (not shown in FIG. 2) for biasing the transistors 32 and 34 to proper operating voltage. Gates G of the transistors 32 and 34 receive a differential signal, then, the transistors 32 and 34 amplify the differential signal and output a corresponding signal from the drains D of the transistors 32 and 34. Sources S of the transistors 32 and 34 are grounded through the capacitors 44 and 46, and form a common mode structure with a series connection of the resistors 40 and 42, where the resistors 40 and 42 are grounded through the current source 48.

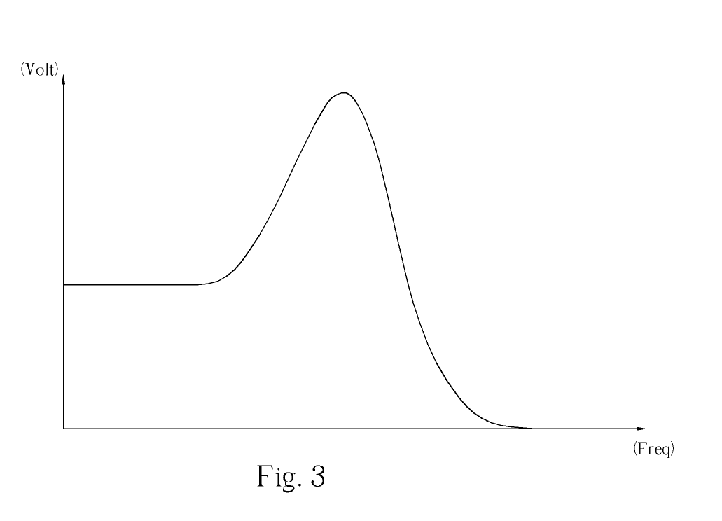

When the equalizer 30 operates in a large signal mode (or an active mode), the capacitors 44 and 46 can be seen as open circuits, so the current source 48 sinks current provided by the transistors 32 and 34 from the drains D to the sources S for maintaining stability. On the other hand, when the equalizer 30 operates in a small signal mode, the capacitors 44 and 46 can be seen as short circuits, so the capacitors 44 and 46 provide a main pole of the transistors 32 and 34 at high frequency. That is, a gain of the equalizer 30 rises rapidly when approaching high frequencies owing to the main pole dominated by the capacitors 44 and 46. The rapidly rising gain compensates for the effects of channel response. Please refer to FIG. 3, which illustrates a frequency-response diagram of the equalizer 30. In FIG. 3, the vertical axis represents variation of amplitude, and the horizontal axis represents variation of frequency. As shown in FIG. 3, the gain of the equalizer 30 increases rapidly after a particular frequency. The effect of channel response can be compensated for, and the bandwidth of the equalizer 30 can be increased, if the capacitances of the capacitors 44 and 46 are set properly according to the channel response.

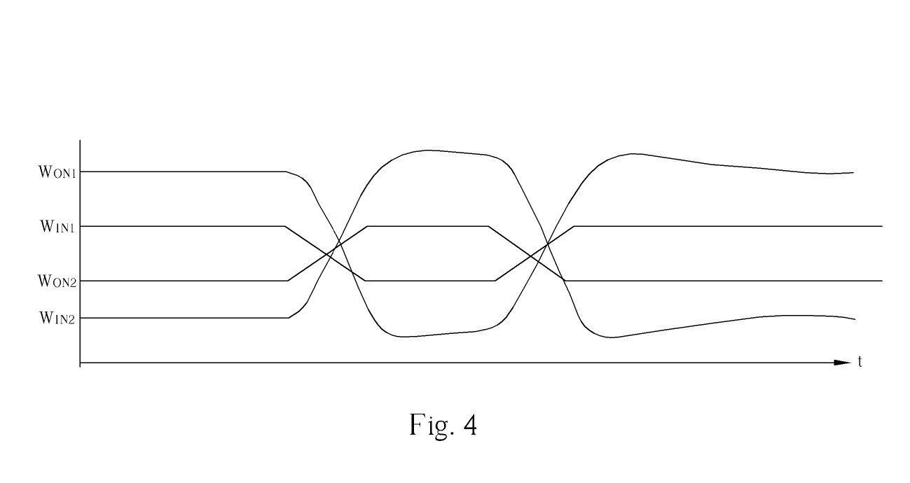

When evaluating a communication system, an eye diagram is used for showing distortion of transmitted signals. The eye diagram is a diagram formed by overlaying a sequence of received impulses in a high-speed oscilloscope. The communication system should increase the scope of □eye□ as widely as possible for preventing decision errors. Please refer to FIG. 4, which illustrates a waveform diagram of input/output signals of the equalizer 30. In FIG. 4, the vertical axis represents variation of amplitude, and the horizontal axis represents variation of time. As mentioned above, the equalizer 30 receives the differential signal from the gates G of the transistors 32 and 34, and outputs the amplified signal from the drains D of the transistors 32 and 34 to the receiver. In FIG. 4, waveforms W_{IN1} and W_{IN2} represent input signals of the gates G of the transistors 32 and 34, while waveforms W_{ON1} and W_{ON2} represent output signals of the drains D of the transistors 32 and 34. Comparing the waveforms W_{IN1} and W_{IN2} with W_{ON1} and W_{ON2}, the signals having been processed by the equalizer 30 increase scope of the eye, which can increase the accuracy of decision and noise rejection.

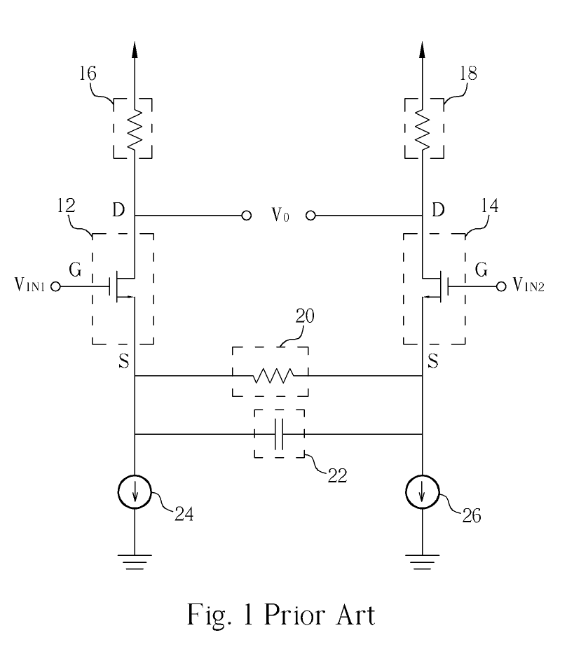

In order to realize high-speed applications, the amplitude of the differential signal received by the equalizer 30 is small, so cross voltages of units in the equalizer 30 is also small. In the prior art equalizer 10 (referring to FIG. 1 ), the cross voltage of the capacitor 22 dominating the main pole of the transistors 12 and 14 is the differential voltage between the sources S of the transistors 12 and 14. As mentioned above, the capacitor 22 cannot apply the MOS capacitor for preventing the capacitance of the capacitor 22 from decreasing when the input signals of the transistors 12 and 14 close to each other. However, in the present invention equalizer 30 (referring to FIG. 2), the capacitors 44 and 46 are between the sources S of the transistors 32 & 34 and ground, so the cross voltages of the capacitors 44 and 46 are differential voltages between the sources S and ground. Therefore, the capacitors 44 and 46 can apply MOS capacitors to decrease the cost of production.

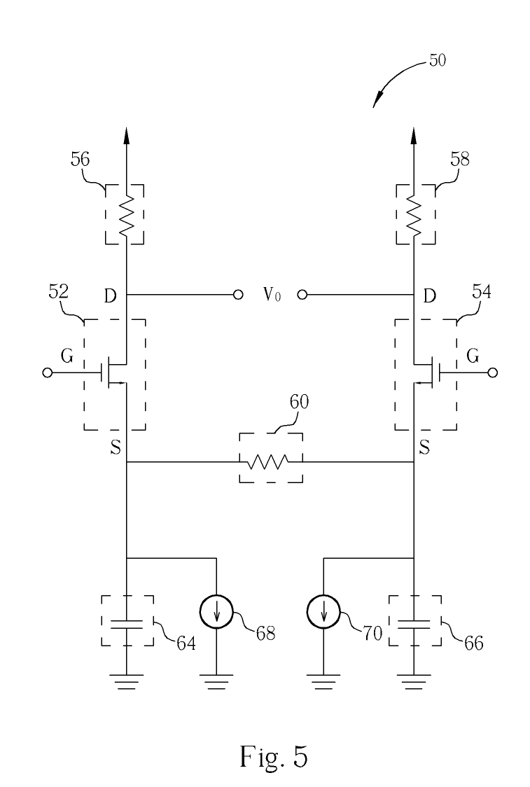

Please refer to FIG. 5, which illustrates a schematic diagram of another embodiment equalizer 50 in accordance with the present invention. The equalizer 50 includes transistors 52, 54, resistors 56, 58, 60, capacitors 64, 66, and current sources 68, 70. The transistors 52 and 54 are MOSFETs. The resistors 56 and 58 connect to drains D of the transistors 52 and 54 respectively as active loads of the transistors 52 and 54. The resistors 56 and 58 also connect to a constant-voltage source (not shown in FIG. 5) for biasing the transistors 52 and 54 to proper operating voltage. Gates G of the transistors 52 and 54 receive a differential signal, then, the transistors 52 and 54 amplify the differential signal, and output a corresponding signal from the drains D of the transistors 52 and 54. Sources S of the transistors 52 and 54 are grounded through the capacitors 64, 66, and the current sources 68, 70, and form a common mode structure with the resistors 60.

Similar to the equalizer 30, when the equalizer 50 operates in large signal mode (or active mode), the capacitors 64 and 66 can be seen as open circuits, so the current sources 68 and 70 sink current provided by the transistors 52 and 54 from the drains D to the sources S for maintaining stability. On the other hand, when the equalizer 50 operates in a small signal mode, the capacitors 64 and 66 can be seen as short circuits, so the capacitors 64 and 66 set the main pole of the transistors 52 and 54 at a high frequency. That is, a gain of the equalizer 50 rises rapidly when approaching high frequency owing to the dominance of the pole set by the capacitors 64 and 66. The rapidly-rising gain compensates for the effects of channel response. The frequency response of the equalizer 50 is similar to the equalizer 30 as shown in FIG. 3, so the effect of channel response can be compensated for, and the bandwidth of the equalizer 50 can be increased if the capacitances of the capacitors 64 and 66 are set properly according to the channel response.

In summary, the present invention equalizers 30 and 50 compensate for the channel response effect with a rising gain at high frequencies, and increase system bandwidth. Meanwhile, the capacitors 44, 46, 64 and 66, the values of which characterize the dominant poles of the equalizers 30 and 50, can be low-cost and low-complexity MOS capacitors, while in the prior art equalizer, the capacitor dominating the main poles must be MMC or PolyC. Therefore, the present invention equalizer can decrease the cost and complexity of production.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An equalizer for a serial data communication receiver comprising:
a first transistor comprising a first input terminal, a first output terminal, and a first equalization terminal;
a second transistor comprising a second input terminal, a second output terminal, and a second equalization terminal;
a first resistor coupled to the first output terminal of the first transistor;
a second resistor coupled to the second output terminal of the second transistor;
a third resistor coupled to the first equalization terminal of the first transistor;
a fourth resistor coupled between the second equalization terminal of the second transistor and the third resistor;
a current source coupled between the third resistor and the fourth resistor;
a first capacitor coupled to the first equalization terminal of the first transistor; and
a second capacitor coupled to the second equalization terminal of the second transistor.

2. The equalizer of claim 1 further comprising a voltage source coupled to the first resistor and the second resistor for providing a bias voltage for the first transistor and the second transistor.

3. The equalizer of claim 1, wherein when the first transistor and the second transistor are n-type metal oxide semiconductor field effect transistors, the first input terminal and the second input terminal are gates of the first transistor and the second transistor, the first output terminal and the second output terminal are drains of the first transistor and the second transistor, and the first equalization terminal and the second equalization terminal are sources of the first transistor and the second transistor.

4. An equalizer for a serial data communication receiver comprising:
a first transistor comprising a first input terminal, a first output terminal, and a first equalization terminal;
a second transistor comprising a second input terminal, a second output terminal, and a second equalization terminal;
a resistor coupled to the first output terminal of the first transistor;
a second resistor coupled to the second output terminal of the second transistor;
a third resistor coupled between the first equalization terminal of the first transistor and the second equalization terminal of the second transistor;
a first current source coupled to the first equalization terminal of the first transistor;
a second current source coupled to the second equalization terminal of the second transistor;
a first capacitor coupled to the first equalization terminal of the first transistor; and
a second capacitor coupled to the second equalization terminal of the second transistor.

5. The equalizer of claim 4 further comprising a voltage source coupled to the first resistor and the second resistor for providing a bias voltage for the first transistor and the second transistor.

6. The equalizer of claim 4, wherein when the first transistor and the second transistor are n-type metal oxide semiconductor field effect transistors, the first input terminal and the second input terminal are gates of the first transistor and the second transistor, the first output terminal and the second output terminal are drains of the first transistor and the second transistor, and the first equalization terminal and the second equalization terminal are sources of the first transistor and the second transistor.
